(19) United States
(12) Patent Application Publication
(10) Pub. No.: US 2023/0031649 A1
(43) Pub. Date: Feb. 2, 2023

(54) STATIC RANDOM-ACCESS MEMORY AND FAULT DETECTION CIRCUIT THEREOF

(71) Applicant: SPREADTRUM COMMUNICATIONS (SHANGHAI) CO., LTD., Shanghai (CN)

(72) Inventor: Zengfa PENG, Shanghai (CN)

(21) Appl. No.: 17/790,244

(22) PCT Filed: Sep. 23, 2020
(86) PCT No.: PCT/CN2020/117029

§ 371 Date: Jun. 30, 2022

(30) Foreign Application Priority Data
Dec. 31, 2019 (CN) 201911409744.8

(51) Int. Cl. G11C 29/52; G11C 11/419

(52) U.S. Cl. CPC G11C 29/52; G11C 11/419

(57) ABSTRACT

A static random-access memory and a fault detection circuit thereof are provided. The fault detection circuit includes: a bit line coupling circuit, coupled between a first bit line and a second bit line, wherein the bit line coupling circuit is adapted to use a bit line with a lower potential between the first bit line and the second bit line to couple a bit line with a higher potential between the first bit line and the second bit line to a floating low potential in response to performing the data write operation on the memory cell in a test mode by the write circuit; and a fault determining circuit, adapted to, in response to the memory cell being at the test mode, obtain and compare write data and read data corresponding to the write data, to determine whether the SRAM has a Data Retention Fault based on a comparison result.

### CROSS-REFERENCE TO RELATED APPLICATIONS

This is the U.S. national stage of application No. PCT/CN2020/117029, filed on Sep. 23, 2020. Priority under 35 U.S.C. § 119(a) and 35 U.S.C. § 365(b) is claimed from Chinese Application No. 201911409744.8, filed Dec. 31, 2019, the disclosure of which is also incorporated herein by reference.

### TECHNICAL FIELD

The present disclosure generally relates to a Static Random-Access Memory, and more particularly, to a Static Random-Access Memory and fault detection circuit thereof.

### BACKGROUND

Static Random-Access Memories (SRAM) are widely used in electronic products. Low power consumption is a very important indicator in electronic products, however, with the increasing application of the SRAM in the digital circuit system, the power consumption of the SRAM accounts for an increasing proportion of the power consumption of the entire digital circuit system.

To prolong chip battery life and minimize static current, the digital circuit system cuts off a temporarily unused SRAM or make it in a sleep state. When the digital circuit system requires the SRAM to be in a sleep state, the SRAM memory cell should keep the data unchanged when a power supply potential of the memory cell is in the low level, so as to realize the purpose of reducing the power consumption of the system greatly.

However, due to process defects of Complementary Metal Oxide Semiconductors (CMOS), the data stored in the SRAM memory cell cannot maintain its inherent state during a long sleep state. After the SRAM wakes up from the sleep state, the digital circuit system may grab wrong data from the SRAM, eventually causing the entire digital circuit system to malfunction. Data retention problems of the SRAM as mentioned above are called Data Retention Faults of SRAM.

However, existing methods for detecting whether there are Data Retention Faults of SRAM is poor in accuracy. There is a need for a fault detection circuit for the SRAM.

### SUMMARY

Embodiments of the present disclosure provide a method for improving the detection accuracy of whether there are Data Retention Faults of SRAM.

In an embodiment of the present disclosure, a fault detection circuit of a Static Random-Access Memory (SRAM) is provided, the SRAM including: a write circuit for performing a data write operation on a memory cell, a read circuit for performing a data read operation on the memory cell, a memory array composed of a plurality of memory cells with each column memory cells sharing a same pair of logical complementary bit lines, wherein the fault detection circuit of the SRAM including: a bit line coupling circuit, coupled between a first bit line and a second bit line, wherein the bit line coupling circuit is adapted to use a bit line with a lower potential between the first bit line and the second bit line to couple a bit line with a higher potential between the first bit line and the second bit line to a floating low potential in response to performing the data write operation on the memory cell in a test mode by the write circuit; and the first bit line and the second bit line are a pair of logical complementary bit lines; and a fault determining circuit, adapted to, in response to the memory cell being at the test mode, obtain and compare write data and read data corresponding to the write data, to determine whether the SRAM has a Data Retention Fault based on a comparison result.

In an embodiment of the present disclosure, a Static Random-Access Memory (SRAM) is provided, including: a fault detection circuit of a SRAM mentioned above.

### BRIEF DESCRIPTION OF THE DRAWINGS

FIG. 1 schematically illustrates a circuit structural diagram of a memory cell in a 6T Static Random-Access Memory (SRAM).

FIG. 2 schematically illustrates an open circuit, or a weak connection of the memory cell as shown in FIG. 1.

FIG. 3 schematically illustrates a structural diagram of a SRAM according to an embodiment of the present disclosure.

FIG. 4 schematically illustrates a circuit structural diagram of a bit line coupling circuit according to an embodiment of the present disclosure.

FIG. 5 schematically illustrates another circuit structural diagram of a bit line coupling circuit according to an embodiment of the present disclosure.

FIG. 6 schematically illustrates a circuit structural diagram of a switch signal generating circuit according to an embodiment of the present disclosure.

FIG. 7 schematically illustrates a circuit structural diagram for detecting a Data Retention Fault on a memory cell in a 6T SRAM according to an embodiment of the present disclosure.

FIG. 8 schematically illustrates a diagram of waveforms of each signal when a logical “1” is successfully written in the memory cell as shown in FIG. 7.

FIG. 9 schematically illustrates a diagram of waveforms of each signal when a logical “1” is unsuccessfully written in the memory cell as shown in FIG. 7.

FIG. 10 schematically illustrates a diagram of connection between a memory array and a bit line coupling circuit according to an embodiment of the present disclosure.

### DETAILED DESCRIPTION

In an existing technology, in order to detect whether there is a Data Retention Fault in a Static Random-Access Memory (SRAM), the usual practice includes: step, writing data to a memory cell, then reading the data in the memory cell and comparing it with the written data to determine whether the data is written correctly; step 2, making the memory into a sleep state and waiting for a long time (more than 100 milliseconds); step 3, waking the memory up from the sleep state, reading the memory cell, and checking whether the data of the memory cell is consistent with the state of the written data.

However, there are disadvantages of the above detection method because the memory cell enters the sleep state, it needs to wait for a long time to wake the memory cell up. In addition, due to defects of the CMOS process, the data written in the memory cell may be reversed due to locking unsuccessfully, which affects the detection accuracy.

In order to shorten the detection time, it is proposed to use an embedded memory BIST technology based on a March algorithm to detect the Data Retention Fault of the SRAM. However, when detecting the Data Retention Fault of the SRAM using the BIST March algorithm, because the time interval between a write operation and a read operation of each memory cell is very short, only some fault types can be detected, and it is difficult to cover all fault types, which leads to a poor detection accuracy.

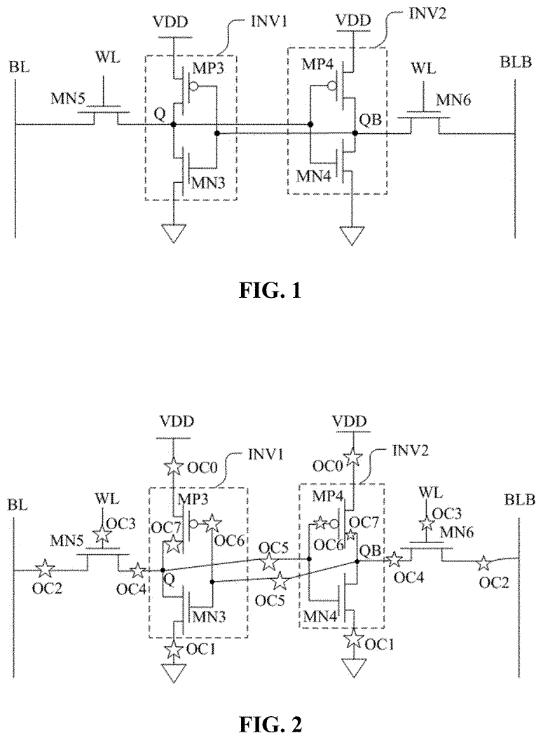

A detailed description is provided given below with reference to FIG. 1 and FIG. 2.

FIG. 1 schematically illustrates a circuit structural diagram of a memory cell in a 6T SRAM. The memory cell has six transistors, which are a third NMOS transistor MN3, a fourth NMOS transistor MN4, a fifth NMOS transistor MN5, a sixth NMOS transistor MN6, a third PMOS transistor MP3 and a fourth PMOS transistor MP4.

Wherein, gates of the fifth NMOS transistor MN5 and the sixth NMOS transistor MN6 are coupled to the word line WL. A source of the fifth NMOS transistor MN5 is coupled to the first bit line BL, a source of the sixth NMOS transistor MN6 is coupled to the second bit line BLB. The third PMOS transistor MP3 and the third NMOS transistor MN3 form an inverter INV1, the fourth PMOS transistor MP4 and the fourth NMOS transistor MN4 form an inverter INV2. The inverter INV1 and the inverter INV2 are coupled end to end.

In the inverter INV1, drains of the third PMOS transistor MP3 and the third NMOS transistor MN3 are coupled to a drain of the fifth NMOS transistor MN5. A source of the third PMOS transistor MP3 is coupled to the power supply potential VDD, and a source of the third NMOS transistor MN3 is grounded.

In the inverter INV2, drains of the fourth PMOS transistor MP4 and the fourth NMOS transistor MN4 are coupled to a drain of the sixth NMOS transistor MN6. A source of the fourth PMOS transistor MP4 is coupled to the power supply potential VDD, and a source of the fourth NMOS transistor MN4 is grounded.

FIG. 2 schematically illustrates an open circuit, or a weak connection of the memory cell as shown in FIG. 1. In the memory cell, when there is an open circuit or a weak connection between OC0 to OC7, it may cause a Data Retention Fault in the SRAM.

When there is an open circuit or a weak connection at OC2, OC3, OC4 or OC5, a Q point of the memory cell cannot be written successfully. Therefore, when detecting the Data Retention Fault of the SRAM using the BIST March algorithm, even if the time interval between the write operation and the read operation of each memory cell is very short, the Data Retention Fault of the memory cell can still be detected. When there is an open circuit or a weak connection at OC1, as long as the operations of writing “0” and reading “0” are performed on the memory cell, a Data Retention Fault of the memory cell can also be detected.

However, when there is an open circuit or a weak connection at 006 or OC7, the Q point can be successfully written to “1”. However, because the open circuit or the weak connection of the third PMOS transistor MP3 cannot supplement the current leaked by the third NMOS transistor MN3, after a long time sleeping of the memory cell, finally the Q point changes from “1” to “0”, and the latched data lost. In this case, when detecting the Data Retention Fault of the SRAM using the BIST March algorithm, because the time interval between the write operation and the read operation of each memory cell is very short, the possible Data Retention Fault of the memory cell cannot be detected.

For a case where there is an open circuit or a weak connection at OC0, if “0” is written in the memory cell, a potential of the first bit line BL is pulled to “0” by a write driver circuit, a potential of the Q point of the memory cell is also pulled to “0”, and a potential of the second bit line BLB is a power supply potential VDD, a potential of the QB point is VDD-Vth, and Vth is a threshold potential of the sixth NMOS transistor. When the read operation is performed on the memory cell, due to the conduction of the third NMOS transistor MN3, the potential of the Q point is pulled to the “0” potential. However, since the read operation may refresh the potential of the QB point during the bit line precharge phase, even if there is an OC0 fault, the result of the read operation is still 0, therefore, it can be determined that there is no Data Retention Fault in the memory cell, and the Data Retention Fault of the memory cell due to an open circuit or a weak connection at OC0 cannot be detected eventually.

It can be seen from the above that for a memory cell, when detecting the Data Retention Fault of the SRAM using the BIST March algorithm, it is difficult to accurately detect the existence of the Data Retention Fault of the memory cell when there is an open circuit or a weak connection at OC0, OC6 or OC7, which may seriously affect the accuracy of detecting the Data Retention Fault of the SRAM using the BIST March algorithm.

In the embodiment of the present disclosure, a fault detection circuit of a SRAM is provided, including: a first bit line coupling circuit, a second bit line coupling circuit and a fault determining circuit. Through the first bit line coupling circuit and the second bit line coupling circuit, when there is a Data Retention Fault in the SRAM, whether data is written through the first bit line or through the second bit line, the data cannot be written in the memory cell successfully, and an error result occurs when data is read from the memory cell, which can determine whether the memory cell has a Data Retention Fault.

In order to clarify the object, characteristic and advantages of embodiments of the present disclosure, the embodiments of present disclosure will be described clearly in detail in conjunction with accompanying drawings.

In the embodiment of the present disclosure, a fault detection circuit of a SRAM is provided. In order to facilitate those skilled in the art to implement the present disclosure more clearly, the static memory is briefly described first.

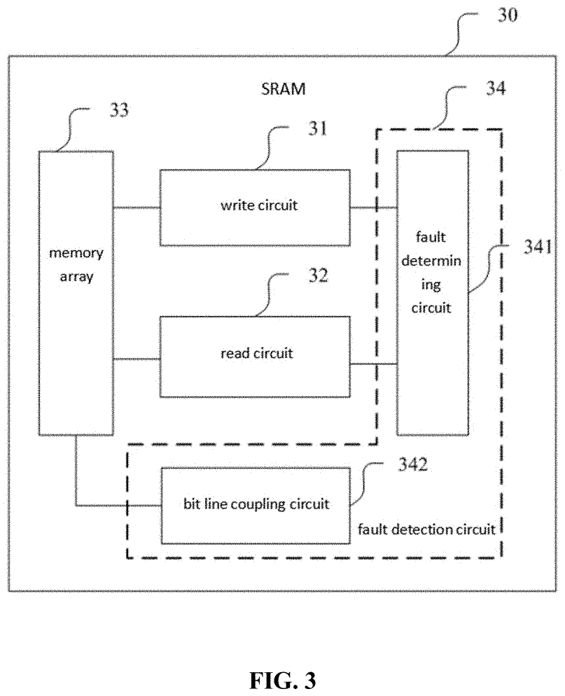

Referring to FIG. 3, the SRAM includes: a write circuit 31 for performing a data write operation on a memory cell, a read circuit 32 for performing a data read operation on the memory cell, and a memory array 33 composed of a plurality of memory cells with each column memory cells share a same pair of logical complementary bit lines, and each row memory cells shares a same word line.

In some embodiment, referring to FIG. 3, the fault detection circuit 34 is usually disposed inside the SRAM 30. In some other embodiment, the fault detection circuit 34 may also be disposed outside the SRAM 30.

In the embodiment of the present disclosure, the fault detection circuit 34 is described in detail by taking the example that the fault detection circuit 34 is disposed inside the SRAM 30. Those skilled in the art can understand that, when the fault detection circuit 34 is disposed outside the SRAM 30, it can be implemented with reference to the specific description about the integration of the fault detection circuit 34 in the SRAM 30, which is not repeated here.

Specifically, the fault detection circuit 34 may include a bit line coupling circuit 341 and a fault determining circuit 342.

The bit line coupling circuit 341 is coupled between a first bit line and a second bit line, and is adapted to use a bit line with a lower potential between the first bit line and the second bit line to couple a bit line with a higher potential between the first bit line and the second bit line to a floating low potential when performing the data write operation to the memory cell in a test mode by the write circuit; and the first bit line and the second bit line are a pair of logical complementary bit lines.

The fault determining circuit 342 is adapted to obtain and compare write data and read data corresponding to the write data, to determine whether the SRAM has a Data Retention Fault based on a comparison result.

In some embodiment, the fault detection circuit 34 performs a fault detection when the SRAM 30 is in a test mode and stops working when the SRAM 30 is in a normal working mode. When the SRAM 30 is in the test mode, the write circuit 31 writes data to the memory cell in the SRAM 30. In this case, the bit line coupling circuit 341 may use a bit line with a lower potential between the first bit line and the second bit line to couple a bit line with a higher potential between the first bit line and the second bit line to a floating low potential. If there is a Data Retention Fault in the SRAM, the data cannot be written in the memory cell successfully. Therefore, the read circuit 32 may read error data from the memory cell, so that the fault determining circuit 342 determines that the SRAM has a Data Retention Fault.

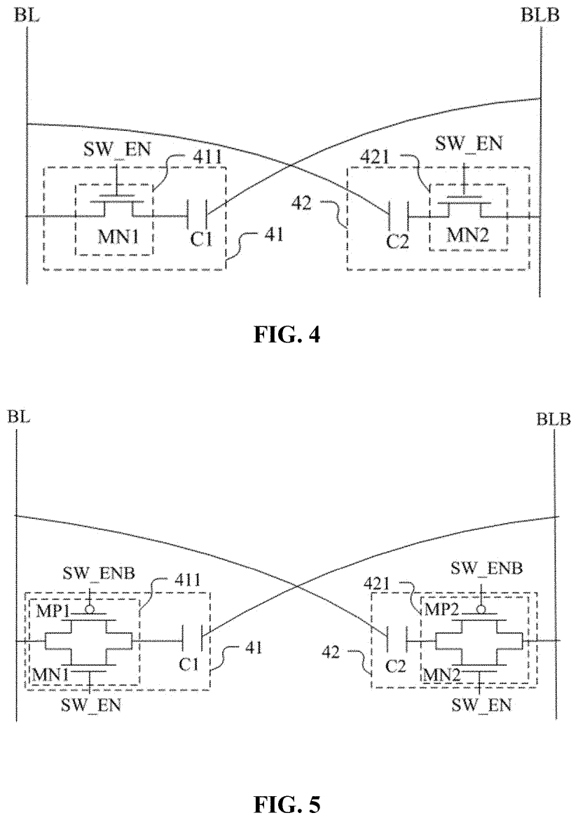

FIG. 4 schematically illustrates a circuit structural diagram of a bit line coupling circuit according to an embodiment of the present disclosure. Referring to FIG. 4, the bit line coupling circuit may include a first bit line coupling circuit 41 and a second bit line coupling circuit 42.

Wherein, the first bit line coupling circuit 41 is coupled between the first bit line BL and the second bit line BLB, when performing the data write operation to the memory cell by the write circuit, the first bit line coupling circuit 41 is adapted to couple a potential of the second bit line BLB to a low level in response to a potential of the first bit line BL being at the low level and the potential of the second bit line BLB being at a high level

The second bit line coupling circuit 42 is coupled between the first bit line BL and the second bit line BLB, when performing the data write operation to the memory cell by the write circuit, the second bit line coupling circuit 42 is adapted to couple the potential of the first bit line BL to the low level in response to the potential of the second bit line BLB being at the low level and the potential of the first bit line BL being at the high level.

In some embodiment, the first bit line coupling circuit 41 and the second bit line coupling circuit 42 may adopt various circuit structures, which are not specifically limited. The circuit structures of the first bit line coupling circuit 41 and the second bit line coupling circuit 42 may be the same or different.

In an embodiment of the present disclosure, the first bit line coupling circuit 41 may include a first switch 411 and a first capacitor C1.

Wherein, one end of the first switch 411 is coupled to the first bit line BL, the other end of the first switch 411 is coupled to the first capacitor C1, the first switch 411 is adapted to be switched on in response to the potential of the first bit line BL being at the low level and the potential of the second bit line BLB being at the high level, and the first switch 411 is adapted to be switched off in response to the potential of the first bit line BL being at the high level and the potential of the second bit line BLB being at the low level.

One end of the first capacitor C1 is coupled to the first switch 411, and the other end of the first capacitor C1 is coupled to the second bit line BLB.

In a specific implementation, a device may be used as the first switch 411.

In an embodiment of the present disclosure, the first switch 411 may include a first NMOS transistor MN1. A drain of the first NMOS transistor MN1 is coupled to the first bit line BL, a source of the first NMOS transistor MN1 is coupled to the first capacitor C1, and a gate of the first NMOS transistor MN1 is coupled to a signal output terminal of the first switch.

In another embodiment of the present disclosure, referring to FIG. 5, the first switch 411 may include a first NMOS transistor MN1 and a first PMOS transistor MP1.

Wherein, a drain of the first NMOS transistor MN1 is coupled to the first bit line BL, a source of the first NMOS transistor MN1 is coupled to the first capacitor C1, and a gate of the first NMOS transistor MN1 is coupled to a signal output terminal of the first switch.

A drain of the first PMOS transistor MP1 is coupled to the first bit line BL, a source of the first PMOS transistor MP1 is coupled to the first capacitor C1, and a gate of the first PMOS transistor MP1 is coupled to a signal output terminal of the second switch.

Wherein, the signal output terminal of the first switch is adapted to output a high level first switch signal SW_EN in response to the potential of the first bit line BL being at the low level and the potential of the second bit line BLB being at the high level, and the signal output terminal of the first switch is adapted to output a low level first switch signal SW_EN in response to the potential of the first bit line BL being at the high level and the potential of the second bit line BLB being at the low level.

The signal output terminal of the second switch is adapted to output a high level second switch signal SW ENB in response to the potential of the first bit line BL being at the high level and the potential of the second bit line BLB being at the low level, and the signal output terminal of the second switch is adapted to output a low level second switch signal SW ENB in response to the potential of the first bit line BL being at the low level and the potential of the second bit line BLB being at the high level.

With the first NMOS transistor MN1 and the first PMOS transistor MP1 as the first switch 411, the resistance of the first switch 411 may be reduced, thereby improving the switching efficiency of the first switch 411, and further improving the speed of writing data to the memory cell.

In an embodiment of the present disclosure, referring to FIG. 4, the second bit line coupling circuit 42 has a same circuit structure as the first bit line coupling circuit 41.

Specifically, the second bit line coupling circuit 42 may include a second switch 421 and a second capacitor C2.

Wherein, one end of the second switch 421 is coupled to the second bit line BLB, the other end of the second switch 421 is coupled to the second capacitor C2, the second switch 421 is adapted to be switched on in response to the potential of the second bit line BLB being at the low level and the potential of the first bit line BL being at the high level, and the second switch 421 is adapted to be switched off in response to the potential of the second bit line BLB being at the high level and the potential of the first bit line BL being at the low level.

One end of the second capacitor C2 is coupled to the second switch 421, and the other end of the second capacitor 421 is coupled to the first bit line BL.

In a specific implementation, a device may be used as the second switch 421.

In an embodiment of the present disclosure, the second switch 421 may include a second NMOS transistor MN2. A drain of the second NMOS transistor MN2 is coupled to the second bit line BLB, a source of the second NMOS transistor MN2 is coupled to the second capacitor C2, and a gate of the second NMOS transistor MN2 is coupled to a signal output terminal of the first switch.

In another embodiment of the present disclosure, referring to FIG. 5, the second switch 421 may include a second NMOS transistor MN2 and a second PMOS transistor MP2.

Wherein, a drain of the second NMOS transistor MN2 is coupled to the second bit line BLB, a source of the second NMOS transistor MN2 is coupled to the second capacitor C2, and a gate of the second NMOS transistor MN2 is coupled to a signal output terminal of the first switch.

A drain of the second PMOS transistor MP2 is coupled to the second bit line BLB, a source of the second PMOS transistor MP2 is coupled to the second capacitor C2, and a gate of the second PMOS transistor MP2 is coupled to a signal output terminal of the second switch.

With the second NMOS transistor MN2 and the second PMOS transistor MP2 as the second switch 421, the resistance of the second switch 421 may be reduced, thereby improving the switching efficiency of the second switch 421, and further improving the speed of writing data to the memory cell.

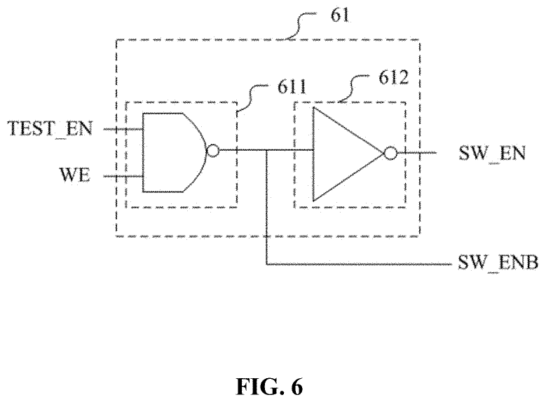

In some embodiment, referring to FIG. 6, the fault detection circuit may further include a switch signal generating circuit 61. The switch signal generating circuit 61 is adapted to generate the first switch signal SW_EN and the second switch signal SW ENB.

In an embodiment of the present disclosure, the switch signal generating circuit 61 may include a NAND gate circuit 611 and an inverter circuit 612.

Wherein, a first input terminal of the NAND gate circuit 611 is adapted to input a test enable signal TEST_EN, a second input terminal of the NAND gate circuit 611 is adapted to input a write enable signal WE, and an output terminal of the NAND gate circuit 611 is adapted to output the second switch signal SW ENB. And an input terminal of the inverter circuit 612 is coupled to the output of the NAND gate circuit 611, an output of the inverter circuit 612 is adapted to output the first switch signal SW_EN.

Wherein, the test enable signal TEST_EN is adapted to control the SRAM to enter a test mode. The write enable signal WE is adapted to control the write circuit to perform a write operation on the memory cell in the SRAM. When the potential of the test enable signal TEST_EN and the potential of the write enable signal WE are at a high level at the same time, the test enable signal TEST_EN and the write enable signal WE are used to control the SRAM to enter the test mode and perform the write operation on the memory cell in the SRAM.

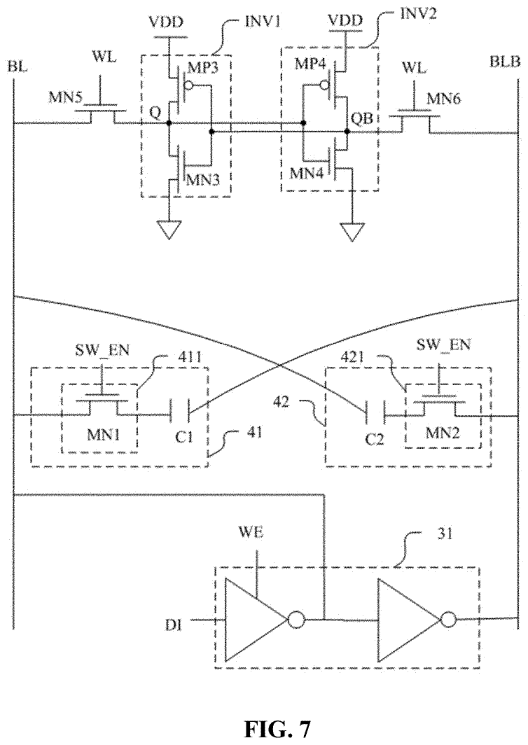

A static memory is taken as an example below, and the static memory is a memory cell of a 6T SRAM shown in FIG. 1. The first bit line coupling circuit 41 and the second bit line coupling circuit 42 are respectively coupled to the first bit line BL and the second bit line BLB of the memory cell in FIG. 1 to obtain a circuit structure diagram as shown in FIG. 7.

The 6T SRAM may include a write circuit 31. The write circuit 31 is composed of two inverters coupled in series. The data written in the write circuit 31 is determined by a write control signal DI. When the write control signal DI changes from logical “1” to logical “0”, logical “1” is written to the memory cell. When the write control signal DI changes from logical “0” to logical “1”, logical “0” is written to the memory cell.

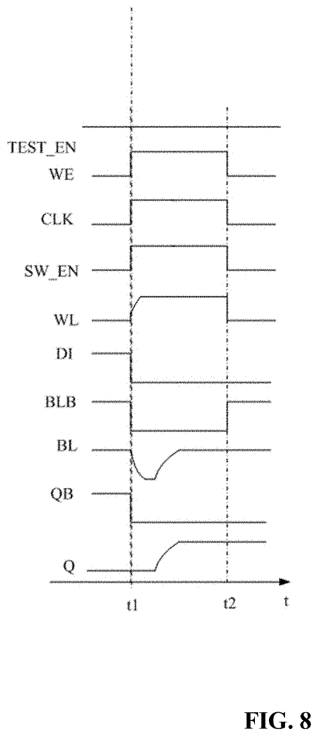

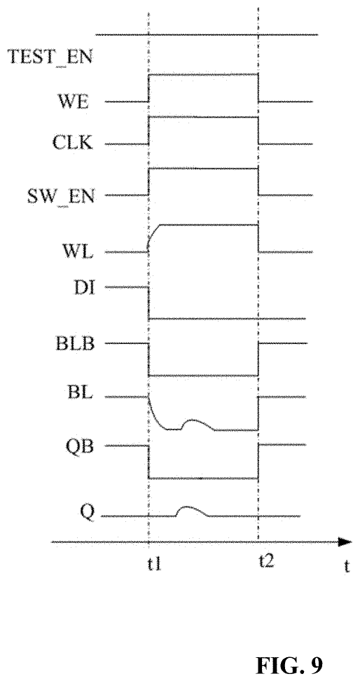

The write circuit 31 writes logical “1” to the memory cell shown in FIG. 7 through the first bit line BL and the second bit line BLB. When the logical “1” is successfully written, that is, the memory cell shown in FIG. 7 does not have an open circuit or a weak connection, the waveforms of the corresponding signals are shown in FIG. 8. When the logical “1” is unsuccessfully written, that is, the memory cell shown in FIG. 7 has an open circuit or a weak connection, the waveforms of the corresponding signals are shown in FIG. 9.

In conjunction with FIG. 7 to FIG. 9, first, the test enable signal TEST_EN is configured logical “1”, the first bit line BL is precharged to VDD (voltage potential) and floats at the VDD potential. At time t1, the SRAM control clock CLK changes from logical “0” to logical “1”, the write enable signal WE changes from logical “0” to logical “1”, and the word line WL changes from logical “0” to logical “1”, the write control signal DI changes from logical “1” to logical “0”, which further pulls the second bit line BLB to logical “0”, and the potential of the memory cell node QB is also pulled to logical “0”.

Since the test enable signal TEST_EN is logical “1” and the write enable signal WE is also logical “1”, the potential of the first switch signal SW_EN is logical “1” and the potential of the second switch signal SW ENB is logical “0”, thus turning the first NMOS transistor MN1 and the second NMOS transistor MN2 on, making the second bit line BLB pass through the first capacitor C1 and the second capacitor C2. The first bit line originally at the VDD potential is coupled to a low potential and floats at the low potential. Accordingly, the potential of the memory cell node Q is pulled to the low potential and floats at the low potential.

If the memory cell has no Data Retention Fault problem, that is, there is no open circuit or weak connection problem at OC0, OC6 or OC7 (as shown in FIG. 2), the potential of the memory cell node QB is logical “0”. In this case, the third NMOS transistor MN3 is switched off, and the third PMOS transistor MP3 is switched on. Therefore, the potential of the memory cell node Q is pulled to logical “1”, and the data writing of the memory cell is successful.

If there is an open circuit or a weak connection problem at OC6 or OC7, or if there is an open circuit or a weak connection problem at OC0, the potential of the memory cell node QB is logical “0”, so that the third NMOS transistor MN3 is switched off. However, the third PMOS transistor MP3 is not switched on or is weakly switched on at the same time, which makes the potential of the memory cell node Q may not be pulled from logical “0” to logical “1”, and the memory cell fails to write data in a short period of time (under a high-speed or a full-speed clock). When a read operation is performed on the memory cell, before time t2, the read data and the written data are inconsistent, therefore, it can be accurately determined that a Data Retention Fault occurs in the memory cell.

If the write circuit 31 writes logical “0” to the memory cell as shown in FIG. 7 through the first bit line BL and the second bit line BLB. Similarly, if the memory cell has no Data Retention Fault problem, the potential of the memory cell node Q is pulled to logical “0”. If the memory cell has a Data Retention Fault problem, the potential of the memory cell node Q may not be pulled from logical “1” to logical “0” in a short time, so it can be accurately determined that the memory cell has a Data Retention Fault.

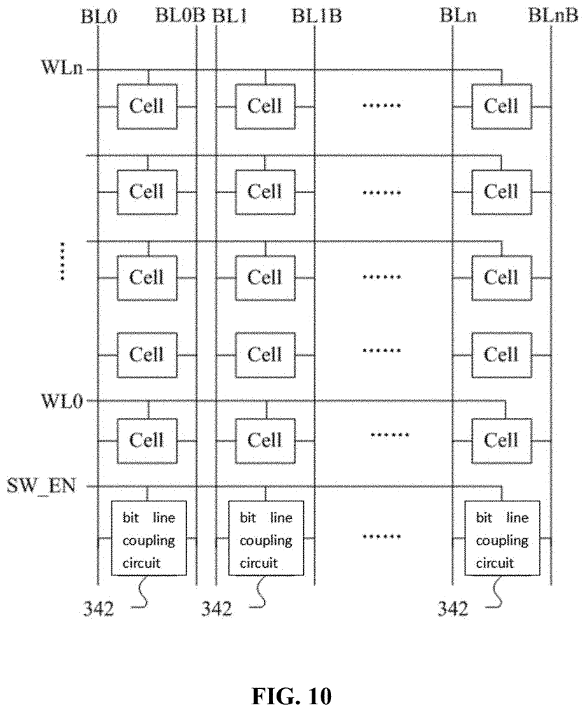

In some embodiment, as shown in FIG. 10, a memory array in the SRAM includes at least two columns of memory cells, the memory cells of each column correspond to a same pair of logical complementary bit lines, and the memory cells of each row correspond to a same word line. For example, the logical complementary bit lines corresponding to the memory cells in the first column are bit line BL0 and bit line BLOB, the logical complementary bit lines corresponding to the memory cells in the second column are bit line BL1 and bit line BL1B, and the logical complementary bit lines corresponding to the memory cells in the last column are bit line BLn and bit line BLnB.

In some embodiment, a bit line coupling circuit 342 may be disposed between each pair of logical complementary bit lines of the SRAM.

In an embodiment of the present disclosure, in order to reduce the chip area occupied by the memory, the bit line coupling circuit is disposed between only one pair of logical complementary bit lines of the SRAM. For example, a bit line selector may be disposed in the SRAM, a pair of logical complementary bit lines may be selected by the bit line selector, and the bit line coupling circuit 342 may be disposed between the selected pair of logical complementary bit lines.

It can be seen from the above that, when performing a write operation to a memory cell, a fault detection circuit of the SRAM in embodiments of the present disclosure use a first capacitor C1 and a second capacitor C2 to realize coupling its complementary bit line to a floating low potential with a bit line to. Therefore, the memory cell having a Data Retention Fault problem cannot write data successfully, so that an error result may occur when data is read from this memory cell, which realizes the purpose of detecting whether there is a Data Retention Fault in the memory cell. Especially when a BIST March algorithm is used to detect the Data Retention Fault of the SRAM, it can not only shorten the test time, but also improve the accuracy of fault detection.

Although the present disclosure is disclosed as above, the present disclosure is not limited to this. Those skilled in the art can make various changes and modifications without departing from the spirit and scope of the present disclosure. Therefore, the protection scope of the present disclosure should be subject to the scope defined by the claims.

1. A fault detection circuit of a Static Random-Access Memory (SRAM), the SRAM comprising: a write circuit for performing a data write operation on a memory cell, a read circuit for performing a data read operation on the memory cell, a memory array composed of a plurality of memory cells with each column memory cells sharing a same pair of logical complementary bit lines, wherein, the fault detection circuit of the SRAM comprising:
a bit line coupling circuit, coupled between a first bit line and a second bit line, wherein the bit line coupling circuit is adapted to use a bit line with a lower potential between the first bit line and the second bit line to couple a bit line with a higher potential between the first bit line and the second bit line to a floating low potential in response to performing the data write operation on the memory cell in a test mode by the write circuit; and the first bit line and the second bit line are a pair of logical complementary bit lines; and
a fault determining circuit, adapted to, in response to the memory cell being at the test mode, obtain and compare write data and read data corresponding to the write data, to determine whether the SRAM has a Data Retention Fault based on a comparison result.

2. The fault detection circuit of the SRAM according to claim 1, wherein the bit line coupling circuit comprises:
a first bit line coupling circuit, coupled between the first bit line and the second bit line, wherein the first bit line coupling circuit is adapted to, in response to performing the data write operation on the memory cell by the write circuit, couple a potential of the second bit line to a low level in response to a potential of the first bit line being at the low level and the potential of the second bit line being at a high level; and
a second bit line coupling circuit, coupled between the first bit line and the second bit line, wherein the second bit line coupling circuit is adapted to, when performing the data write operation on the memory cell by the write circuit, couple the potential of the first bit line to the low level in response to the potential of the second bit line being at the low level and the potential of the first bit line being at the high level.

3. The fault detection circuit of the SRAM according to claim 2, wherein the first bit line coupling circuit comprises a first switch and a first capacitor, and wherein
one end of the first switch is coupled to the first bit line, the other end of the first switch is coupled to the first capacitor, the first switch is adapted to be switched on in response to the potential of the first bit line being at the low level and the potential of the second bit line being at the high level, and the first switch is adapted to be switched off in response to the potential of the first bit line being at the high level and the potential of the second bit line being at the low level; and
one end of the first capacitor is coupled to the first switch, and the other end of the first capacitor is coupled to the second bit line.

4. The fault detection circuit of the SRAM according to claim 3, wherein the first switch comprises:
a first NMOS transistor, a drain of the first NMOS transistor being coupled to the first bit line, a source of the first NMOS transistor being coupled to the first capacitor, and a gate of the first NMOS transistor being coupled to a signal output terminal of the first switch.

5. The fault detection circuit of the SRAM according to claim 3, wherein the first switch comprises a first NMOS transistor and a first PMOS transistor, and wherein
a drain of the first NMOS transistor is coupled to the first bit line, a source of the first NMOS transistor is coupled to the first capacitor, and a gate of the first NMOS transistor is coupled to a signal output terminal of the first switch; and
a drain of the first PMOS transistor is coupled to the first bit line, a source of the first PMOS transistor is coupled to the first capacitor, and a gate of the first PMOS transistor is coupled to a signal output terminal of the second switch;
the signal output terminal of the first switch is adapted to output a high level first switch signal in response to the potential of the first bit line being at the low level and the potential of the second bit line being at the high level, and the signal output terminal of the first switch is adapted to output a low level first switch signal in response to the potential of the first bit line being at the high level and the potential of the second bit line being at the low level; and
the signal output terminal of the second switch is adapted to output a high level second switch signal in response to the potential of the first bit line being at the high level and the potential of the second bit line being at the low level, and the signal output terminal of the second switch is adapted to output a low level second switch signal in response to the potential of the first bit line being at the low level and the potential of the second bit line being at the high level.

6. The fault detection circuit of the SRAM according to claim 3, wherein the second bit line coupling circuit comprises a second switch and a second capacitor, and wherein
one end of the second switch is coupled to the second bit line, the other end of the second switch is coupled to the second capacitor, the second switch is adapted to be switched on in response to the potential of the second bit line being at the low level and the potential of the first bit line being at the high level, and the second switch is adapted to be switched off in response to the potential of the second bit line being at the high level and the potential of the first bit line being at the low level; and
one end of the second capacitor is coupled to the second switch, and the other end of the second capacitor is coupled to the first bit line.

7. The fault detection circuit of the SRAM according to claim 6, wherein the second switch comprises:
a second NMOS transistor, a drain of the second NMOS transistor being coupled to the second bit line, a source of the second NMOS transistor being coupled to the second capacitor, and a gate of the second NMOS transistor being coupled to a signal output terminal of the first switch.

8. The fault detection circuit of the SRAM according to claim 6, wherein the second switch comprises a second NMOS transistor and a second PMOS transistor, and wherein
a drain of the second NMOS transistor is coupled to the second bit line, a source of the second NMOS transistor is coupled to the second capacitor, and a gate of the second NMOS transistor is coupled to a signal output terminal of the first switch; and
a drain of the second PMOS transistor is coupled to the second bit line, a source of the second PMOS transistor is coupled to the second capacitor, and a gate of the second PMOS transistor is coupled to a signal output terminal of the second switch;
the signal output terminal of the first switch is adapted to output a high level first switch signal in response to the potential of the first bit line being at the low level and the potential of the second bit line being at the high level, and the signal output terminal of the first switch is adapted to output a low level first switch signal in response to the potential of the first bit line being at the high level and the potential of the second bit line being at the low level; and
the signal output terminal of the second switch is adapted to output a high level second switch signal in response to the potential of the first bit line being at the high level and the potential of the second bit line being at the low level, and the signal output terminal of the second switch is adapted to output a low level second switch signal in response to the potential of the first bit line being at the low level and the potential of the second bit line being at the high level.

9. The fault detection circuit of the SRAM according to claim 5, further comprising:
a switch signal generating circuit, adapted to generate the first switch signal and the second switch signal.

10. The fault detection circuit of the SRAM according to claim 9, wherein the switch signal generating circuit comprises a NAND gate circuit and an inverter circuit, and wherein
a first input terminal of the NAND gate circuit is adapted to input a test enable signal, a second input terminal of the NAND gate circuit is adapted to input a write enable signal, and an output terminal of the NAND gate circuit is adapted to output the second switch signal; and
an input terminal of the inverter circuit is coupled to the output of the NAND gate circuit, an output of the inverter circuit is adapted to output the first switch signal.

11. A Static Random-Access Memory (SRAM), comprising: a fault detection circuit of a SRAM according to claim 1.

12. The SRAM according to claim 11, wherein a bit line coupling circuit is disposed between each pair of logical complementary bit lines of the SRAM.

13. The SRAM according to claim 11, wherein a bit line coupling circuit is disposed between one pair of logical complementary bit lines of the SRAM.

14. The fault detection circuit of the SRAM according to claim 8, further comprising:
a switch signal generating circuit, adapted to generate the first switch signal and the second switch signal.

15. The fault detection circuit of the SRAM according to claim 14, wherein the switch signal generating circuit comprises a NAND gate circuit and an inverter circuit, and wherein
a first input terminal of the NAND gate circuit is adapted to input a test enable signal, a second input terminal of the NAND gate circuit is adapted to input a write enable signal, and an output terminal of the NAND gate circuit is adapted to output the second switch signal; and
an input terminal of the inverter circuit is coupled to the output of the NAND gate circuit, an output of the inverter circuit is adapted to output the first switch signal.
